(19) United States
(12) Patent Application Publication
(10) Pub. No.: US 2016/0108524 A1
(43) Pub. Date: Apr. 21, 2016

(54) HIGH-SPEED DEPOSITION OF MIXED OXIDE BARRIER FILMS

(71) Applicant: LOTUS APPLIED TECHNOLOGY, LLC, Hillsboro, OR (US)

(72) Inventors: Eric R. Dickey, Hillsboro, OR (US); Bryan Larson Danforth, Portland, OR (US)

(73) Assignee: LOTUS APPLIED TECHNOLOGY, LLC, Hillsboro, OR (US)

(21) Appl. No.: 14/885,431

(22) Filed: Oct. 16, 2015

Related U.S. Application Data
(60) Provisional application No. 62/065,487, filed on Oct. 17, 2014.

(51) Int. Cl. C23C 16/455; C23C 16/06

(52) U.S. Cl. CPC C23C 16/45536; C23C 16/06

(57) ABSTRACT

The present disclosure relates to metal oxide barrier films and particularly to high-speed methods for depositing such barrier films. Methods are disclosed that are capable of producing barrier films with water vapor transmission rates (WVTR) below 0.1 g/(m²·day). Methods are disclosed for continuously transporting a substrate within an atomic layer deposition (ALD) reactor and performing a limited number of ALD cycles to achieve a desired WVTR.

### CROSS-REFERENCE TO RELATED APPLICATIONS

Under 35 U.S.C. §119(e), this application claims the benefit of U.S. Provisional Patent Application No. 62/065,487, entitled “HIGH-SPEED DEPOSITION OF MIXED OXIDE BARRIER FILMS,” filed Oct. 17, 2014, the contents of which are hereby incorporated herein by reference in their entirety.

### TECHNICAL FIELD

The present disclosure relates to metal oxide barrier films and particularly to high-speed methods for depositing such barrier films.

### BACKGROUND

Atomic layer deposition (ALD) is similar to conventional chemical vapor deposition (CVD) processes but distinct in its self-limiting growth at the surface of the substrate on an atomic level. Traditionally, ALD film growth has been accomplished through sequential pulsing and purging of two separate precursors in a common reaction volume containing the substrate. See, e.g., U.S. Pat. No. 4,058,430. ALD is a process that generates thin films that are extremely conformal, highly dense, and provide pinhole-free coverage. These attributes make ALD particularly suitable for high-quality barrier films, and several organizations have shown that thin single-layer ALD barrier films are capable of delivering “ultra-barrier” performance suitable for highly moisture-sensitive applications including thin film photovoltaics (TFP) and organic light emitting diodes (OLED).

The ALD process has been commercialized for applications in the semiconductor industry, but has not been commercialized for applications in the commercial packaging industry. To date, the commercialized semiconductor-grade ultra-barrier processes have extremely low growth rates and are incompatible with moving substrates. In contrast, commercial packaging operations tend to utilize high-speed webs. Additionally, the barrier performance of commercial packaging is often several orders of magnitude less stringent than the barrier performance required for semiconductor-grade barriers.

A need remains for an ALD process that could be used with moving substrates to produce barrier films that meet the less stringent barrier performance specifications of the commercial packaging industry.

### BRIEF DESCRIPTION OF THE DRAWINGS

FIG. 1 is similar to FIG. 1 of U.S. Pat. Nos. 8,137,464 and 8,202,366.

FIG. 2 is similar to FIG. 4 of U.S. Patent Application Publication No. 2012/0021128.

FIG. 3 is a schematic of the non-limiting exemplary bench-top, research-scale reactor used in the experiments of Example 1.

FIG. 4 depicts a non-limiting graphical plot of film growth rate as a function of web speed for the mixed oxide atomic layer deposition (ALD) coatings deposited during the experiments of Example 1.

FIG. 5 depicts a non-limiting graphical plot of barrier performance as measured by water vapor transmission rate (WVTR) as a function of film thickness over several production rates tested in Example 1.

### DETAILED DESCRIPTION

The present disclosure relates to metal oxide barrier films and particularly to high-speed methods for depositing such barrier films. Among other possible applications, the embodiments disclosed herein may be used to make commercial packaging with suitable water vapor transmission rates.

In some embodiments of methods of making a barrier layer on a substrate, the methods may comprise continuously transporting the substrate at a speed of at least about 2 meters per second (m/s) within an atomic layer deposition (ALD) reactor. The methods may further comprise depositing one of alumina or titania on a portion of the substrate in a first ALD cycle, while the substrate is moving and then depositing the other one of alumina or titania on the same portion of the substrate in a second ALD cycle, while the substrate is moving, and repeating the deposition steps for a total of about 50 or less ALD cycles, thereby forming a barrier layer comprising alumina and titania and having a water vapor transmission rate (WVTR) of less than about 0.1 g/(m²·day).

In some of such embodiments, depositing one of alumina or titania may comprise depositing one of alumina or titania about five or fewer consecutive times, about four or fewer times, about three or fewer times, about two or fewer times, or one time before depositing the other one of alumina or titania. Or stated another way, the first ALD cycle may be repeated five or fewer times before depositing the other one of alumina or titania on the same portion of the substrate in the second ALD cycle.

In some of such embodiments, depositing one of alumina or titania on a portion of the substrate in a first ALD cycle may comprise depositing one of alumina or titania on a portion of the substrate in a first plasma-enabled ALD cycle. For example, depositing one of alumina or titania on a portion of the substrate in a first ALD cycle, while the substrate is moving, may comprise exposing a portion of the substrate to a precursor while the substrate is moving, moving the substrate to an isolation zone, and then exposing the same portion of substrate to an oxygen- and nitrogen-containing plasma while the substrate is moving. Examples of precursors include an isopropoxide and a metalorganic. Accordingly, in another example, depositing one of alumina or titania on a portion of the substrate may comprise exposing the portion of the substrate to one of an isopropoxide or a metalorganic.

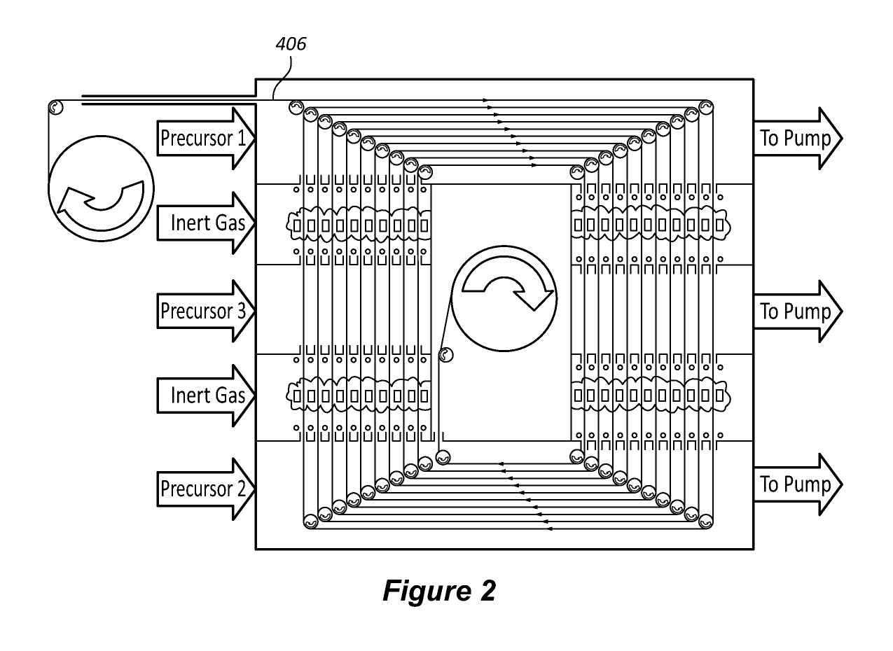

In some of such embodiments, depositing one of alumina or titania on a portion of the substrate in a first ALD cycle while the substrate is moving may comprise isolating with air a precursor gas from the ALD reactor. The air may be dry air. The dry air may be unfiltered. For example, the substrate may travel into a precursor zone where a precursor chemisorbs onto the surface of the substrate, the substrate may travel to an isolation zone where air removes non-chemisorbed precursor from the surface of the substrate, and then the substrate may move into a plasma zone where a plasma is formed from air and plasma radicals react with the precursor to deposit either alumina or titania. Likewise, in another example, the plasma may be formed in the isolation zone, such as in FIG. 2, which is discussed in more detail below.

In some of such embodiments, repeating the deposition steps for a total of about 50 or less ALD cycles, thereby forming a barrier layer comprising alumina and titania and having a water vapor transmission rate (WVTR) of less than about 0.1 g/(m²·day) may comprise forming the barrier layer in about 45 or less ALD cycles, about 40 or less ALD cycles, about 35 or less ALD cycles, about 30 or less ALD cycles, or about 25 or less ALD cycles, or about 20 or less ALD cycles.

For example, forming a barrier layer comprising alumina and titania and having a WVTR of less than about 0.01 g/m²/day in about 25 or less ALD cycles may comprise continuously transporting the substrate at a speed of at least about 2.5 m/s. In that example, the thickness of the barrier layer after the about 25 or less ALD cycles may be at least about 3 nm, at least about 3.5 nm, or at least about 4 nm.

In another example, forming a barrier layer comprising alumina and titania and having a WVTR of less than about 0.01 g/(m²·day) in about 25 or less ALD cycles may comprise continuously transporting the substrate at a speed of at least about 5 m/s. In that example, the thickness of the barrier layer after about 25 or less ALD cycles is at least about 4 nm, at least about 4.5 nm, or at least about 5 nm.

In still another example, forming a barrier layer comprising alumina and titania and having a WVTR of less than about 0.01 g/(m²·day) in about 35 or less ALD cycles may comprise continuously transporting the substrate at a speed of at least about 8 m/s. In that example, the thickness of the barrier layer after about 35 or fewer ALD cycles may be at least about 5 nm, at least about 5.5 nm, or at least about 6 nm.

In still yet another example, forming a barrier layer comprising alumina and titania and having a WVTR of less than about 0.01 g/(m²·day) in about 50 or fewer ALD cycles while continuously transporting the substrate at a speed of at least about 10 m/s. In that example, the thickness of the barrier layer after about 50 or fewer ALD cycles may be at least about 6.5 nm, at least about 7 nm, or at least about 7.5 nm.

In some of such embodiments, the barrier layer may comprise a mixed oxide comprising alumina and titania.

In some embodiments of methods of making a barrier layer on a substrate, the methods may comprise continuously transporting the substrate at a speed of at least about 2 meters per second (m/s) within an ALD reactor. The methods may further comprise exposing a portion of the substrate to one of an isopropoxide or a metalorganic, exposing the same portion of the substrate to an oxygen- and nitrogen-containing plasma, exposing the same portion of the substrate to the other of the isopropoxide or the metalorganic, and then exposing the same portion of the substrate again to an oxygen- and nitrogen-containing plasma, thereby forming a mixed oxide barrier layer having a thickness of at least about 3 nm after about 50 or less ALD cycles.

In some of such embodiments, exposing a portion of the substrate to one of an isopropoxide or a metalorganic comprises exposing the substrate to one of an isopropoxide or a metalorganic about five or fewer consecutive times before exposing the same portion of the substrate to the other one of the isopropoxide or the metalorganic.

In some of such embodiments, the mixed oxide may comprise alumina and titania.

In some of such embodiments, forming a mixed oxide barrier layer having a thickness of at least about 3 nm occurs after about 45 or less ALD cycles, after about 40 or less ALD cycles, after about 35 or less ALD cycles, after about 30 or less ALD cycles, after about 25 or less ALD cycles, or after about 20 or less ALD cycles.

In any of the foregoing embodiments, the barrier layer may have a WVTR of less than about 0.1 g/(m²·day), about 0.05 g/(m²·day), about 0.01 g/(m²·day), less than about 0.005 g/(m²·day), or less than about 0.001 g/(m²·day). The WVTR may be determined at 38° C. and 90% relative humidity at atmospheric pressure and pursuant to ASTM-1249.

In any of the foregoing embodiments, the methods may further comprise isolating isopropoxide and metalorganic within the ALD reactor with air. Likewise, in any of the foregoing embodiments, the oxygen- and nitrogen-containing plasma may comprise a plasma formed from air. In each case, the air may be dry air. The air may also be unfiltered air. Alternatively, the oxygen- and nitrogen-containing plasma may comprise a plasma formed from N₂ and O₂ in a ratio different from that of air.

In any of the foregoing embodiments, the oxygen- and nitrogen-containing plasma may comprise a plasma formed from nitrogen and oxygen sources other than N₂ and O₂.

In any of the foregoing embodiments, the plasma may be designed to provide a high concentration of reactive oxygen radicals close to the substrate surface, so as to avoid energetic ion bombardment of the substrate.

In any of the foregoing embodiments, the isopropoxide may comprise titanium tetraisopropoxide (TTIP). Likewise, in any of the foregoing embodiments, the metalorganic may comprise trimethylaluminum (TMA). The precursors may or may not be semiconductor-grade precursors in the foregoing embodiments. For example, the TTIP may comprise at least about 3% impurities, at least about 2% impurities, or at least about 1% impurities. Likewise, in another example, the TMA may comprise at least about 2% impurities or at least about 1% impurities.

In any of the foregoing embodiments, the substrate may comprise a flexible film, such as, by way of non-limiting examples, polyethylene terephthalate, polypropylene, biaxially-oriented polypropylene, polyetheretherketone, polyimide, or polyethylene naphthalate.

In any of the foregoing embodiments, the temperature of the ALD reactor may be maintained at about 100° C. or less.

In any of the foregoing embodiments, continuously transporting the substrate at a speed of at least about 2 m/s within the ALD reactor may comprise continuously transporting the substrate at a speed of at least about 2.5 m/s, at least about 3 m/s, at least about 3.5 m/s, at least about 4 m/s, at least about 4.5 m/s, at least about 5 m/s, at least about 5.5 m/s, at least about 6 m/s, at least about 6.5 m/s, at least about 7 m/s, at least about 7.5 m/s, at least about 8 m/s, at least about 8.5 m/s, at least about 9 m/s, at least about 9.5 m/s, or at least about 10 m/s within the ALD reactor.

In any of the foregoing embodiments, continuously transporting the substrate may comprise moving the substrate as a web from a feed roll to an uptake roll. For example, the web may move back and forth between at least a first precursor zone, an isolation zone, and a second precursor zone, such as in a serpentine fashion. Or, the web may move back and forth in a spiral fashion between at least a first precursor zone, an isolation zone, and a second precursor zone.

In any of the foregoing embodiments, the mixed oxide may essentially be a homogeneous mixture of titania and alumina (i.e., a TiAlₓO_{y} phase) without discrete alumina or titania sublayers as occurs with nano-laminates.

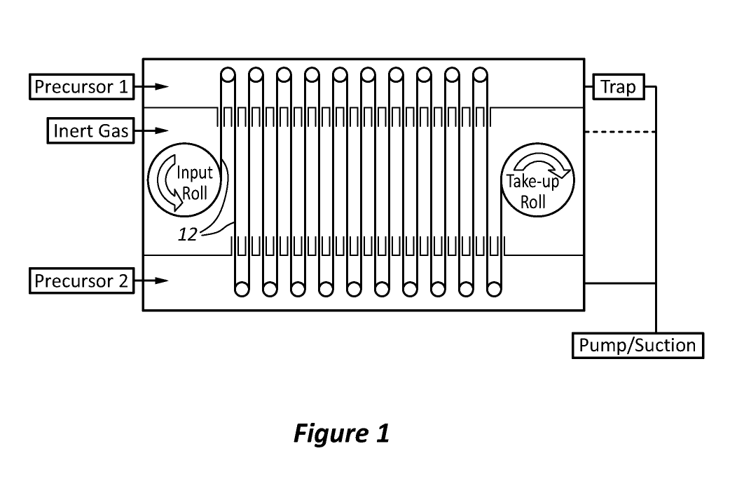

U.S. Pat. Nos. 8,137,464 and 8,202,366, the contents of both of which are incorporated herein by reference in their entirety, respectively, disclose embodiments of roll-to-roll plasma-enabled ALD reactors that could be used in the embodiments disclosed herein. FIG. 1 is similar to U.S. Pat. Nos. 8,137,464 and 8,202,366. In one example of how the embodiments of U.S. Pat. Nos. 8,137,464 and 8,202,366 could be used with the embodiments disclosed herein, Precursor 1 and Precursor 2 of FIG. 1 could be TTIP and TMA, respectively and vice versa. Likewise, the Inert Gas (i.e., source gas for the plasma) could be dry, unfiltered air and a plasma generated in the isolation zone between the precursor zones (not illustrated). The flexible substrate 12 could be continuously transported at a speed of at least about 2 m/s. Other examples from U.S. Pat. Nos. 8,137,464 and 8,202,366 could likewise apply to the embodiments disclosed herein.

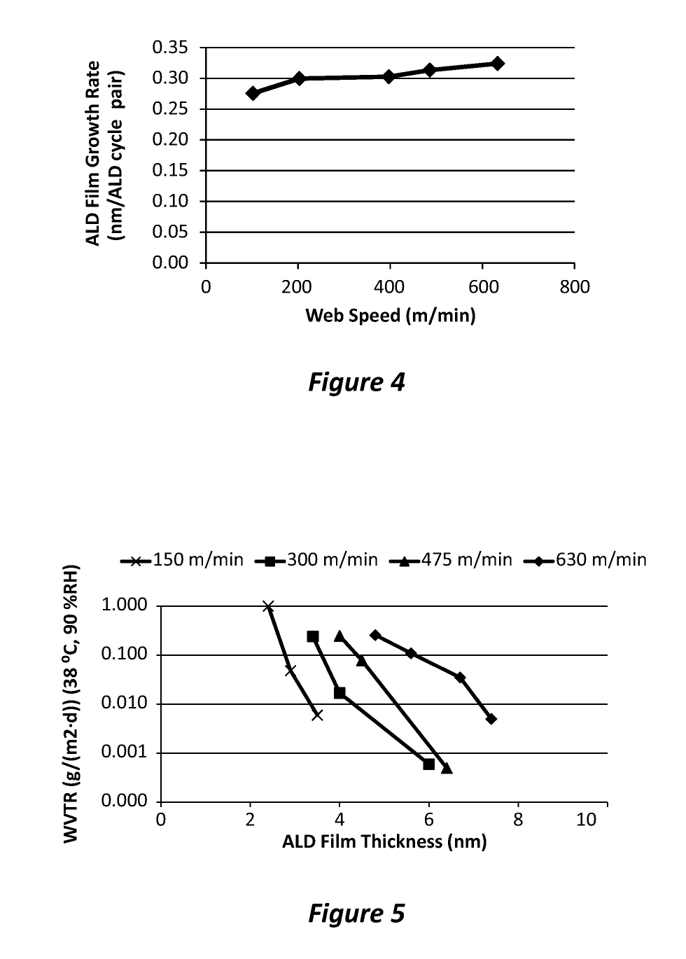

U.S. Patent Application Publication No. 2012/0021128, the contents of which are incorporated herein by reference in their entirety, discloses embodiments of roll-to-roll plasma-enabled ALD reactors that could be used in the embodiments disclosed herein. FIG. 2 is similar to FIG. 4 of U.S. Patent Application Publication No. 2012/0021128. In one example of how the embodiments of U.S. Patent Application Publication No. 2012/0021128 could be used with the embodiments disclosed herein, Precursor 1 and Precursor 2 of FIG. 2 could both be TTIP and Precursor 3 could be TMA (alternatively, Precursor 1 and Precursor 2 may be TMA and Precursor 3 may be TTIP). The Inert Gas could be dry, unfiltered air (i.e., source gas for plasma) and a plasma generated in the isolation zone between the precursor zones (illustrated as clouds). Plasma generations in an isolation zone, and other alternatives, are disclosed in more detail in U.S. Patent Application Publication No. 2012/0021128. The substrate 406 could be continuously transported at a speed of at least about 2 m/s. Other examples from U.S. Patent Application Publication No. 2012/0021128 could likewise apply to the embodiments disclosed herein.

### Example 1

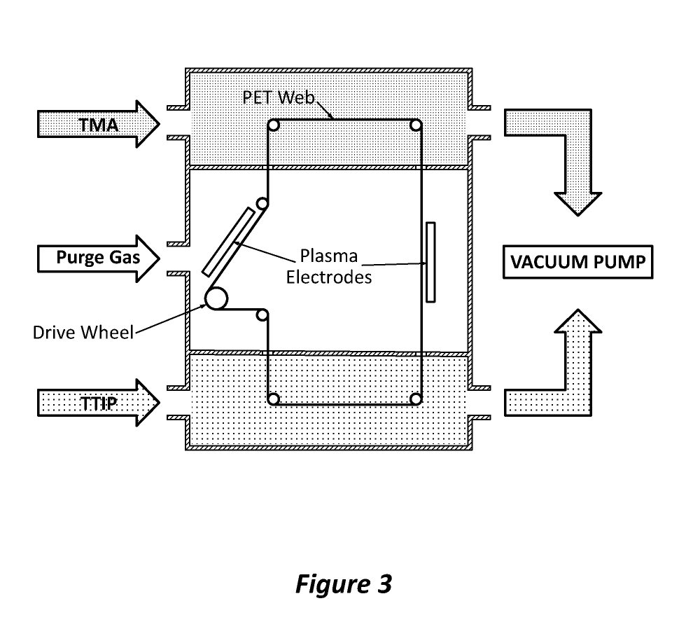

The mixed metal oxide thin films made in this Example were produced on a bench-top, research-scale reactor, schematically represented in FIG. 3. The reactor comprised an aluminum vacuum chamber that was externally heated by resistive heat pads. The internals of the reactor were physically separated into three zones by two metal plates. These separator plates each had two slots, which allowed for web entry and exit through the precursor zones. ALD precursors were fed into each of the top and bottom zones, while dry air purge gas (i.e., isolation gas) was introduced to the central zone of the reactor. Pumping was applied, via a mechanical pump and roots blower, to only the top and bottom zones. This combination resulted in a positive pressure in the center zone, with the outward sweeping of purge gas from the center zone into the top and bottom zones preventing migration of precursor gasses out of their respective zones. For the oxidation steps of the ALD cycles, two electrodes approximately 13 cm square were located in the central zone of the reactor, spaced about 1 cm from the web surface. A direct-current diode plasma was generated from the electrodes using an Advanced Energy MDX 500 magnetron sputtering power supply. Using an operating pressure nominally in the range of 1 Torr, the direct-current diode plasma was confined to within approximately 5 mm of the electrode surface. This provided a high concentration of reactive oxygen radicals to the substrate surface, while avoiding energetic ion bombardment of the substrate.

A closed band of substrate material was formed around six guide rollers and one drive roller, as illustrated in FIG. 3. As the band circulated through one full lap, one pair of ALD cycles was generated, including one cycle from the precursor in the top zone and the other from the precursor in the bottom zone. The number of ALD cycle pairs, and the associated ALD film thickness, was controlled simply by the number of laps completed. It is important to note that in this configuration, a nominally homogenous mixture of the two oxides was deposited rather than a nano-laminate structure. This was because each ALD cycle resulted in an average film growth of only about 0.1 to 0.15 nm film thickness, far less than the thickness of even a single molecular layer of a binary oxide. Additionally, it is expected that the mixed oxide comprised TiAlₓO_{y}, such that there would be no detectable sublayers of alumina and titania when viewed by transmission electron microscopy (TEM).

Rolls of four-inch wide, 500-μm thick DuPont Melinex® ST-504 PET web were used in lengths of 2.2 m for closed loop circulation. The original substrate material was slit and rewound by a third-party converter in an industrial environment, with no special procedures used to prevent contamination or damage. The barrier coating was deposited exclusively on the raw PET side of the web, without any smoothing layers, and no additional cleaning of the substrate was done prior to the ALD deposition. Of course, in other examples, cleaning steps could be performed. Polyimide tape was used to secure web splices. Prior to metal oxide film deposition, a short oxygen plasma pretreatment was done to activate the polymer surface.

Dry air, generated by a central facilities commercial air compressor and dryer, was used as the purge and plasma gas. For all runs conducted in this study, a total plasma current of 1 amp was used, which was split between the pair of electrodes. Trimethylaluminum (TMA), 98% pure, was passively evaporated from a room temperature source into the top zone. Titanium tetraisopropoxide (TTIP), 97% pure, was heated to 85° C. and passively evaporated into the bottom zone. The deposition chamber was isotropically heated to 100° C. In the loop configuration, the substrate band was continuously circulated for a set number of revolutions to deposit a corresponding film thickness.

Thickness values for mixed metal oxide barrier films on PET were not directly measurable because the refractive indices of the coating and substrate were so similar. Instead, witness pieces of silicon were taped onto the PET to accompany each run. Following each deposition trial, the ALD film thickness was measured on the silicon piece using ellipsometry.

Thin film elemental composition analysis was performed on ALD films approximately 50 nm thick deposited on silicon. Rutherford Backscattering Spectrometry (RBS) was used to determine elemental concentrations of Ti, Al, 0, and C. In addition, Hydrogen Forward Scattering (HFS) was implemented to measure H content.

Water vapor transmission rate (WVTR) was measured using two different instruments during the study. Samples were first measured on an Illinois Instruments Water Vapor Transmission Analyzer Model 7001 with a detection limit specified at 3×10⁻³ g/(m²·day). For samples which measured below this detection limit, additional tests were run using a MOCON Aquatran analyzer with a sensitivity range specified at 5×10⁻⁴ g/(m²·day). All WVTR data were collected at 38° C. temperature and 90% relative humidity and pursuant to ASTM-1249.

In order to characterize the impact of web speed on film growth rate, several trials were conducted in which the web was circulated approximately 31 revolutions (62 alternating ALD cycles) while at various substrate translation intervals. Growth rate was calculated by dividing total film thickness by the number of pairs of completed ALD cycles, expressed as nm/ALD pair. As shown in FIG. 4, film deposition rate rose about 17% over a 520% increase in web speed, indicating a high degree of growth rate saturation, indicating ALD processes were occurring on the substrate.

The results from compositional analysis of the ALD films deposited at 150, 300, and 600 meters per minute are tabulated below in Table 1. This table shows film elemental composition as a function of web speed for mixed oxide ALD coatings deposited in the research reactor.

TABLE 1

| Web Speed | | | | | |
|---|---|---|---|---|---|
| (m/min) | Ti (at %) | Al (at %) | O (at %) | C (at %) | H (at %) |
| 150 | 8.5 | 22.5 | 57.8 | <3 | 11 |
| 300 | 7.2 | 21.3 | 56.8 | <3 | 14.5 |
| 640 | 6.3 | 19.2 | 50.1 | 5 | 19 |

As displayed in Table 1, titanium and aluminum concentrations decreased as web speed increased. Simultaneously, carbon and hydrogen increased as web speed increased. This data indicates that under the plasma conditions used, at higher web speeds, the oxidation of the chemisorbed precursor was likely incomplete, resulting in residual carbon, and higher concentrations of hydrogen in the film.

Barrier performance was characterized by measuring WVTR over a range of film thicknesses, deposited at various web speeds. The results are displayed in FIG. 5. Films in the range of 3.5 nm to 7.5 nm thick, produced at web speeds ranging from 150 to 630 meters per minute, have been shown to provide WVTR levels below 0.01 g/(m²·day) at 38° C. and 95% relative humidity. For all web speeds tested, up to 630 meters per minute, WVTR values of less than 1×10⁻² g/(m²·day) were achieved for ALD coatings less than 8 nm thick.

Generally, as the web speed was increased, a thicker coating was required to achieve the desired barrier performance of WVTR values of less than 1×10⁻² g/(m²·day). Without wishing to be bound by theory, this may be due to increased contamination (e.g., hydrogen and carbon) levels in the film resulting from incomplete oxidation of the chemisorbed precursor. A higher plasma power or more efficient plasma source is expected to increase the complete oxidation and thereby reduce the contamination. This suggests that even the films made at the higher speeds shown in FIG. 4 could be made at a reduced thickness and still achieve a desired barrier performance.

### Example 2

By way of non-limiting example, FIG. 1 could be used for deposition on 300 mm wide rolls of material up to 500 meters long using the serpentine web configuration for plasma-assisted ALD processing. This tool features 25 roller pairs that can be setup in a three-zone configuration or a five-zone configuration, which enable 50 or 100 ALD cycles in a single pass, respectively. The serpentine configuration scales well for relatively thick (from a commercial packaging standpoint) substrate material and widths up to 1 to 1.5 meters. For these types of substrate material, contact between the guide rollers and the ALD-coated substrate surface may be prevented by using stand-offs at the outer edges of the web.

### Example 3

Many commercial barrier packaging applications require wide substrate material, up to 2.5 meters wide, and very thin material, in the range of 8μ to 25μ. For substrates this wide and thin, preventing roller contact by using edge standoffs is much more difficult. For these applications, an alternative “coil” configuration may be used for the substrate path. In this configuration, the web follows a spiraling path, from an outer wind/unwind roller to a central wind/unwind roller, such as illustrated in FIG. 2.

With this configuration, only one side of the substrate contacts the guide rollers, while the other side is coated with the ALD film. The entire width of the web can be directly supported through all turns, without damaging the ALD coating. From the results shown in Example 1, only very thin coatings are needed for excellent commercial barrier films, allowing as few as five to 10 coil layers in a high-volume manufacturing reactor, capable of producing barriers with WVTR in the range of 0.01 to 0.001 g/(m²·day).

It will be apparent to those having skill in the art that many changes may be made to the details of the above-described embodiments and examples without departing from the underlying principles of the invention.

1. A method of forming a barrier layer on a substrate, the method comprising:
continuously transporting the substrate at a speed of at least about 2 meters per second (m/s) within an atomic layer deposition (ALD) reactor; and
depositing one of alumina or titania on a portion of the substrate in a first ALD cycle, while the substrate is moving; and
depositing the other one of alumina or titania on the same portion of the substrate in a second ALD cycle, while the substrate is moving,
repeating the deposition steps for a total of about 50 or less ALD cycles, thereby forming a barrier layer comprising alumina and titania and having a water vapor transmission rate (WVTR) of less than about 0.1 g/(m²·day).

2. The method of claim 1, wherein the barrier layer comprises a mixed oxide comprising alumina and titania.

3. The method of claim 1, further comprising repeating the first ALD cycle five or fewer times before depositing the other one of alumina or titania on the same portion of the substrate in the second ALD cycle.

4. The method of claim 1, wherein the substrate comprises a flexible film.

5. The method of claim 1, further comprising continuously transporting the substrate at a speed of at least about 5 m/s.

6. The method of claim 1, further comprising forming a barrier layer comprising alumina and titania and having a WVTR of less than about 0.1 g/(m²·day) in about 20 or less ALD cycles.

7. The method of claim 1, wherein the barrier layer has a WVTR of less than about 0.001 g/(m²·day).

8. The method of claim 1, further comprising maintaining the temperature of the ALD reactor at about 100° C. or less.

9. The method of claim 1, wherein the barrier layer comprises at least about 10% impurity atoms.

10. A method of forming a barrier layer on a substrate, the method comprising:
continuously transporting the substrate at a speed of at least about 2 meters per second (m/s) within an atomic layer deposition (ALD) reactor;
exposing a portion of the substrate to one of an isopropoxide or a metalorganic;
exposing the same portion of the substrate to an oxygen- and nitrogen-containing plasma;
exposing the same portion of the substrate to the other of the isopropoxide and the metalorganic;
exposing the same portion of the substrate again to an oxygen- and nitrogen-containing plasma, thereby forming a mixed oxide barrier layer having a thickness of at least about 3 nm after about 50 or less ALD cycles.

11. The method of claim 10, wherein the oxygen- and nitrogen-containing plasma comprises a plasma formed from air.

12. The method of claim 10, wherein the mixed oxide comprises alumina and titania.

13. The method of claim 10, wherein exposing a portion of the substrate to one of an isopropoxide or a metalorganic comprises exposing the substrate to one of an isopropoxide or a metalorganic in about five or less complete plasma-enabled ALD cycles before exposing the same portion of the substrate to the other one of the isopropoxide or the metalorganic in a different complete plasma-enabled ALD cycle.

14. The method of claim 10, wherein the isopropoxide comprises titanium tetraisopropoxide (TTIP).

15. The method of claim 10, wherein the metalorganic comprises trimethylaluminum (TMA).

16. The method of claim 10, wherein continuously transporting the substrate comprises moving the substrate on a web from a feed roll to an uptake roll.

17. The method of claim 16, wherein the web moves back and forth between at least a first precursor zone, an isolation zone, and a second precursor zone within the ALD reactor, wherein exposing a portion of the substrate to one of an isopropoxide or a metalorganic occurs in the first precursor zone, wherein exposing the same portion of the substrate to an oxygen- and nitrogen-containing plasma occurs in the isolation zone, wherein exposing the same portion of the substrate to the other of the isopropoxide and the metalorganic occurs in the second precursor zone, wherein exposing the same portion of the substrate again to an oxygen- and nitrogen-containing plasma occurs in the isolation zone.

18. The method of claim 16, wherein the web moves back and forth in either a serpentine fashion or a spiral fashion between at least a first precursor zone, an isolation zone, and a second precursor zone within the ALD reactor, wherein exposing a portion of the substrate to one of an isopropoxide or a metalorganic occurs in the first precursor zone, wherein exposing the same portion of the substrate to an oxygen- and nitrogen-containing plasma occurs in the isolation zone, wherein exposing the same portion of the substrate to the other of the isopropoxide and the metalorganic occurs in the second precursor zone, wherein exposing the same portion of the substrate again to an oxygen- and nitrogen-containing plasma occurs in the isolation zone.

19. The method of claim 10, wherein the barrier layer comprises about 15% impurity atoms.

20. The method of claim 10, wherein the barrier layer has a water vapor transmission rate (WVTR) of less than about 0.001 g/(m²·day).
